(19) United States
(12) Patent Application Publication
(10) Pub. No.: US 2007/0001239 A1
(43) Pub. Date: Jan. 4, 2007

(54) Mis transistor with self-aligned gate and method for making same

(76) Inventor: Simon Deleonibus, CLAIX (FR)

Correspondence Address: Thelen Reid & Priest, P O Box 640640, San Jose, CA, 95164-0640, US

(21) Appl. No.: 10/539,928

(22) PCT Filed: Dec. 15, 2003
(86) PCT No.: PCT/FR03/50173

§ 371 Date: May 2, 2006

(30) Foreign Application Priority Data
Dec. 16, 2002 (FR) 02 15916

(51) Int. Cl. H01L 29/76

(52) U.S. Cl. 257/408

(57) ABSTRACT

An MIS transistor having a T shaped gate is characterised by the presence of a shaping material (14) coating a T shaped solid form. The gate structure is lodged in the envelope formed by the shaping material (14). The coating of the T shape of the gate by the shaping material (14) is carried out at the very start of forming the gate structure and is chosen in such a way that it withstands all subsequent manufacturing treatments of the transistor and subsists, thus defining the definitive shape of the gate structure. One thus obtains a perfectly controlled gate shape.

### TECHNICAL FIELD

The present invention concerns a self aligned gate MIS transistor and its method of manufacture. MIS transistor is taken to mean a transistor with a Metal-Insulator-Semiconductor type structure such as, for example, MOS transistors (Metal-Oxide-Semiconductor).

More specifically, the invention concerns the manufacture of said transistors on a silicon substrate, capable of operating in the hyperfrequencies domain.

The invention finds applications in micro-electronics for the manufacture of hyperfrequency circuits and/or power circuits, for example for forming circuits that may be used in the field of telecommunications.

### STATE OF THE PRIOR ART

In a known manner, hyperfrequency type components and circuits are normally formed on gallium arsenide (AsGa) substrates or on silicon substrates (Si).

For reasons of cost, the circuits formed on gallium arsenide substrates are generally not very complex and do not have a high integration density. Consequently, the architecture of said circuits is not optimised from a point of view of their compactness.

The appended FIG. 1 gives an example of a hyperfrequency component, in this particular case an MOS (Metal Oxide Semi-conductor) transistor, formed on a silicon substrate.

The transistor of FIG. 1 comprises a source region 10, a channel region 12 and a drain region 14 defined in a silicon substrate 16. The source 10 and the drain 14 are, for example, formed by implanting n type doping impurities if the channel 12 is p type, or p type if the channel 12 is n type.

An insulating layer of silicon oxide 18 is formed on the surface of the substrate 16 and covers the source 10, channel 12 and drain 14 regions.

A non-passing through opening 20 is formed by etching in the oxide layer 18, substantially directly above the channel region 12. At the base of the opening 20, a thin layer 22 of oxide forms a gate insulation. A gate 24 is finally formed in the opening 20 above the gate insulation layer 22.

The material forming the gate 24, as it happens a metal, has a low resistivity and thus allows the transistor formed to operate at high frequency.

The integration density of the devices formed according to FIG. 1 depends on the precision with which the opening 20, and consequently the gate 24, are aligned in relation to the channel 12 and in relation to the source and drain 10, 14 regions. This precision depends directly on the quality of the tools used to manufacture (particularly the alignment) the semi-conductor devices.

In a known manner, within the scope of forming MOS transistor integrated circuits on a silicon substrate, one solution for increasing the compactness and the integration density of circuits consists in self aligning the gate 24 in relation to the source and drain 10, 14 zones.

One considers that the gate 24 is self aligned in relation to the source and drain zones 10, 14 when the relative position of the gate 24 and the source and drain zones 10, 14 does not result from an alignment of the means used (masks for example) for forming these parts, but when the position of the source and drain zones 10, 14 is directly defined by the position of the gate 24 itself. In a practical manner, the self alignment of the gate in relation to the source and drain regions results from a method of forming the source and drain regions 10, 14 in which said regions are formed by implantation of impurities in the substrate by using the gate, formed previously, as implantation mask. The position of the gate thus precisely and automatically fixes the position of the source 10 of the channel 12 and of the drain 4.

The methods for forming transistors with a gate that is self aligned in relation to the source and drain zones generally involves thermal treatments carried out at high temperature. By way of example, in the methods of forming self aligned gate MOS transistors on silicon, a thermal treatment at a temperature of around 750° C. or more is carried out after the implantation of impurities, in order to activate the source and drain sources.

Moreover, a densification or a creep of insulator placed between the gate and the first level of interconnection metal is carried out in a substantially identical temperature range. Moreover, as evoked above, it is necessary to use a gate material of low resistivity to obtain a transistor operating at high frequency. By way of indication, during the manufacture of hyperfrequency type devices, in other words devices that operate in general at a frequency greater than 100 MHz, the gate material used for forming the transistors must have preferentially a resistivity between around 1 and 100 μΩ·cm.

It turns out that the materials with a resistivity situated in the range indicated either are not capable of withstanding the thermal treatment temperatures used in the indicated methods for manufacturing self aligned gate transistors, or withstand said temperatures but diffuse and contaminate the adjacent layers, reducing their performance.

A material frequently used for forming the gate of self aligned gate transistors is polycrystalline silicon (poly Si). Polycrystalline silicon is indeed capable of withstanding the temperature, commonly of around 750° C., of the thermal treatments carried out during the formation of said transistors. The resistivity of polycrystalline silicon, of around 10³ μΩ·cm, is not compatible with the envisaged applications of transistors in the hyperfrequency domain. Moreover, it is not known how to sufficiently reduce the resistivity of the polycrystalline silicon to obtain a hyperfrequency operation of the transistors. Most metals are also capable of withstanding the thermal treatments, but they diffuse into the adjacent layers, which transforms the performance of said layers.

Thus, for example, it is often difficult to use a gate material of low resistivity such as copper (Cu) or silver (Ag) compatible with the CMOS integration. In the case of Cu, the diffusion in the silicon oxide, including below 400° C., is very rapid and necessitates the use of a barrier material, such as for example titanium nitride (TiN), for preventing the diffusion. TiN is known to be a good barrier for Cu but the use of this material is limited to supply voltages greater than or equal to 1.5 volts. Silver oxidises very easily, including at low temperature, which increases its resistivity. Ag is thus also difficult to use. Given the fact that one cannot use the least resistive materials, it is known to reduce the gate resistance by using a T shaped gate having a vertical bar, the underneath of which is located above an insulating layer overhanging the channel. The overall impedance of the gate, in particular the parasite capacity (Miller capacity) between the gate and the source and the drain and the source is low, since the overlap surface between the gate and the source or the gate and the drain is limited to the section of the vertical bar of the T. The resistance of the gate itself is reduced by the presence of the horizontal bar of the T, which is wider than the vertical bar. The transistor formed with such a T shaped gate may be self aligned or not. As explained above, the use of the non self aligned gate adversely affects the integration density of devices using this technology.

A known example of forming a transistor having a T shaped gate and a source and a drain self aligned on said gate is described in the patent FR 2 757 312 (U.S. Pat. No. 6,346,450) of the same inventor.

In this embodiment, the method of manufacturing an MIS transistor (Metal-Insulator-Semi-conductor) on a semiconductor substrate comprises the following steps:
a) the formation on the substrate of a dummy gate consisting of one or several material(s) capable of withstanding a thermal treatment. The dummy gate is formed, for example, by formation on the substrate of a stacking of layers comprising, in the order, a layer of oxide known as a pedestal layer, a layer of polycrystalline or amorphous silicon and a layer of silicon nitride. One then carries out the shaping of the stacking by etching in order to constitute the shape of the dummy gate with lateral sides.
b) the formation in the substrate of source and drain regions self-aligned on the dummy gate,
c) the lateral coating of the dummy gate with at least one electrically insulating material,
d) the elimination of the dummy gate and the formation in the place of the dummy gate of a definitive gate consisting of one or several material(s) of low resistivity, the definitive gate being separated from the substrate by a gate insulating layer.

This type of method, in which the position of the gate is firstly occupied by a dummy gate, said dummy gate being replaced in a terminal phase by the definitive gate, is known as the damascene method.

The dummy gate, formed in the course of the method, has a double function: it makes it possible, firstly, to define the position of the source and drain regions during the step b), then to define the position of the definitive gate of the transistor in low resistivity material. Indeed, the coating of the dummy gate on its lateral sides forms, after the elimination of said dummy gate, a “mould” for the definitive gate.

In an embodiment described in the above-mentioned patent, the transistor is as represented in FIG. 2 of the drawing appended to the present application. This figure corresponds to FIG. 5 of the aforesaid patent. The description that follows of this figure is intended to highlight an example of the state of the manufacturing stage of a transistor, before elimination of the dummy gate. It describes the state of the transistor at this stage of manufacture independently of the embodiments for arriving at this state.

On a silicon substrate 100, for example p doped, are implanted gradual source and drain regions marked in FIG. 2 with the references 118 and 120. Said regions 118, 120 are implanted on either side of a channel zone 112. A layer of silicide, formed above the source 118 and drain 120 regions, is indicated with references 119 and 121 respectively.

A stacking 110 of layers forming together the dummy gate is implanted above the channel 122 and the layer of silicide 119, 121. Said stacking comprises a layer 114 known as a thermal oxide layer, the lower part of which comes immediately above the layers 119, 121 and the channel 122. A central part of the stacking 110 comprises above the layer 114 of thermal oxide, a layer of polycrystalline or amorphous silicon 104 then a layer of silicon nitride 106. The sides of this central part are edged from the interior towards the exterior by an upraising of the layer 114 of thermal oxide, lateral spacers 116 for example in silicon oxide doped with phosphorous or PSG (phosphosilicate glass), and finally another layer 124 in silicon oxide doped with phosphorous. Said final layer 124 edges the lateral sides of the stacking 110 at the level of the spacers 116 and also comes above the layers 119, 121 of silicide. The lower part of the spacers 116 rests on a peripheral part of the layer 114.

A layer 126, either of intrinsic silicon oxide not intentionally doped, or of borophosphosilicate (BPSG) is located above the layer 124 and coats the gate stacking 110.

The total thickness of the layers 104 and 106 is, for example, around 100 to 500 nm and corresponds substantially to the thickness of the gate of the transistor that will be finally obtained at the end of the method of manufacture.

The example that has been described here above in relation to FIG. 2, has been given in order to highlight the fact that the chemical attack that is going to be carried out from this manufacturing stage, to form an opening, the shape of which is going to determine the definitive shape of the T shaped gate, must meet states that are difficult to meet and which lead to dispersions of dimensions and shapes of openings that are detrimental on the one hand to an integration in CMOS devices of 60 nm or less technology since one controls poorly the size of an opened out part of the opening intended to form the horizontal bar of the T of the future gate. Furthermore, one also controls poorly the dimensions of the lower part of the vertical bar of the T, which leads to a risk of increasing the covering of the source and drain by the gate, and consequently to a risk of increasing the Miller capacity, which is detrimental to a high frequency operation.

From the state represented in FIG. 2, the elimination of the dummy gate comprises a final chemical etching step for example with hydrofluoric acid. In order to obtain an opened out shape for the opening, corresponding substantially to the T shape that one wishes to obtain for the gate, a specific choice for the materials for the layers 114, 116, 124 and 126 must be made. The acid attack, more or less rapid depending on the materials, makes it possible to open out an opening 130 represented in FIG. 3, according to a specific chosen profile. In the case of the example described, it involves, seen as a cross-section, a T profile.

Indeed, by way of example, the rate of attack of the layer of lateral spacers 116 in PSG is 5 times higher than the rate of attack of the thermal oxide 114 and 3 times higher than the rate of attack of the intrinsic oxide of the layer 126. If the layer 126 is in borophosphosilicate (BPSG), one notes that the rate of attack of the PSG is 6 times higher than that of BPSG.

As a general rule, the shape of the opening out obtained for the horizontal bar of the T is dependent on the attack of the lateral spacers, the size of which depends first of all on the optimisation of the source and drain and that must be manufactured with a material having a rate of attack higher than the material used for the planarisation.

### DESCRIPTION OF THE INVENTION

The aim of the invention is to propose an MOS transistor with improved performance compared to the transistors of the prior art.

A further aim is to propose such a particularly compact transistor compatible with the formation of CMOS circuits (complementary MOS) with a high integration density.

The invention concerns an MIS transistor, having a gate resistance and a Miller capacity of controlled and reproducible value with a very high cut off frequency allowing operation in a range of hyperfrequencies for example above 200 gigahertz.

In one embodiment, the invention further concerns a transistor having leakage currents lower than those of the prior art.

A further aim of the invention is to propose methods for forming such a transistor.

Consequently, one aim of the present invention is to propose a method for manufacturing a MIS transistor with self aligned gate, source and drain and capable of operating in the range of hyperfrequencies.

To all of these ends the invention relates to a self aligned MIS transistor having a source zone and a drain zone on either side of a channel zone, as well as a gate structure in the shape of a T composed on a vertical bar located above the channel zone, surmounted by a horizontal bar extending on either side of the vertical bar, said horizontal bar having a lower part, a lateral part and an upper part, the gate structure consisting of a stacking of one or several conductive layers, a base zone of the gate structure being defined as being around the base of the vertical bar of the T, characterised in that the gate structure is coated in a shaping material, said material covering the base zone of the structure, the vertical bar of the T, and the lower and lateral-parts of the horizontal bar of the T.

The expressions horizontal and vertical or upper and lower used in the present application do not refer to the terrestrial horizontal direction and vertical direction. By convention, the horizontal direction is that of the plane of a wafer bearing the transistors, and the vertical direction is the direction perpendicular to said wafer.

In one embodiment, the first extension zones between the channel and source and drain zones respectively have a doping of the same nature as the source and drain zones but weaker.

In another embodiment, the second extension zones between the channel and source and drain zones respectively or between the channel zones and the first extension zones have a doping of a nature opposite to that of the source and drain sources.

The invention further concerns a method for manufacturing on a semiconductor substrate at least one self aligned MIS transistor having a source zone and a drain zone on either side of a channel zone, as well as a T shaped gate structure composed of a vertical bar located above the channel zone, surmounted by a horizontal bar extending on either side of the vertical bar, said horizontal bar having a lower part, a lateral part and an upper part, the gate structure consisting of a stacking of one or several conductive layers, a base zone of the gate structure being defined as being around the base of the vertical bar of the T, characterised in that it comprises a step of forming a solid shape having the T shape of the gate that one wishes to form, and the coating of said shape in a shaping material, said material covering the base zone of the gate structure, the vertical bar of the T, and the lower and lateral parts of the horizontal bar of the T of the definitive gate.

When it is said that the coating material covers the base zone of the gate structure, the vertical bar of the T, and the lower and lateral parts of the horizontal bar of the T of the definitive gate, it is meant that said material will be conserved throughout the subsequent manufacturing steps, and will remain in the transistor. It therefore involves a material capable of withstanding all of the chemical treatments subsequent to its application.

In one embodiment, the shaping material covers a part at least of the source and drain zones.

Preferably the coating material will consist of silicon nitride Si₃N₄, hafnium oxide HfO₂, zirconium oxide ZrO₂ or even aluminium oxide Al₂O₃.

In the case where the initial material forming the initial solid shape coated by the shaping material is not the material forming the gate, it may be for the vertical bar of T a metal or polycrystalline silicon and for the horizontal bar a twin layer formed by a first under layer of polycrystalline silicon, or of a metal or a silicide, and of a second under layer of silica or silicon nitride. The material forming the definitive gate may, for its part, be for example a metal or polycrystalline silicon.

In the case where the initial material forming the initial solid shape coated by the shaping material is the initial material forming the gate, it may be for the vertical bar of the T oxidisable metal or polycrystalline silicon and for the horizontal bar of a metal or a silicide for the first under layer and of silica or silicon nitride for the second under layer.

Preferably, when the coating material consists of silicon nitride Si₃N₄, the material constituting the initial solid shape may be polycrystalline silicon and the final material of metal or polycrystalline silicon. When the initial material is the same as the final gate material it may be oxidisable metal or polycrystalline silicon.

Preferably when the coating material consists of hafnium oxide HfO₂, the material constituting the initial solid shape may be a metal or polycrystalline silicon and the final material metal or polycrystalline silicon. When the initial material is the same as the final gate material it may be oxidisable metal or polycrystalline silicon.

Preferably when the coating material consists of zirconium oxide ZrO₂, the material constituting the initial solid shape may be a metal or polycrystalline silicon and the final material a metal or polycrystalline silicon. When the initial material is the same as the final gate material it may be a metal or polycrystalline silicon

### BRIEF DESCRIPTION OF DRAWINGS

Other characteristics and advantages of the invention will become clearer from the description that follows in reference to the appended drawings in which:

FIG . 1, already described, is a schematic cross section of a known type of MOS transistor formed on a solid semi-conductor substrate;

FIG. 2, already described, is a schematic cross section representing a step of forming a transistor having a T shaped gate;

FIG. 3, already described, is a schematic cross section of a step of forming a transistor representing in particular the shape of a T shaped opening in which a gate will be inserted.

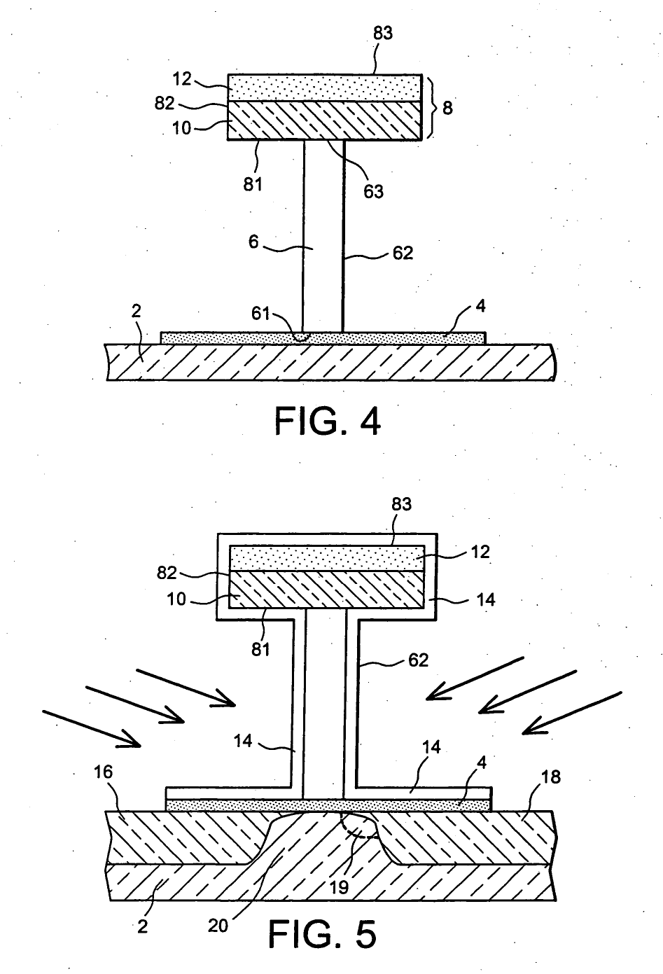

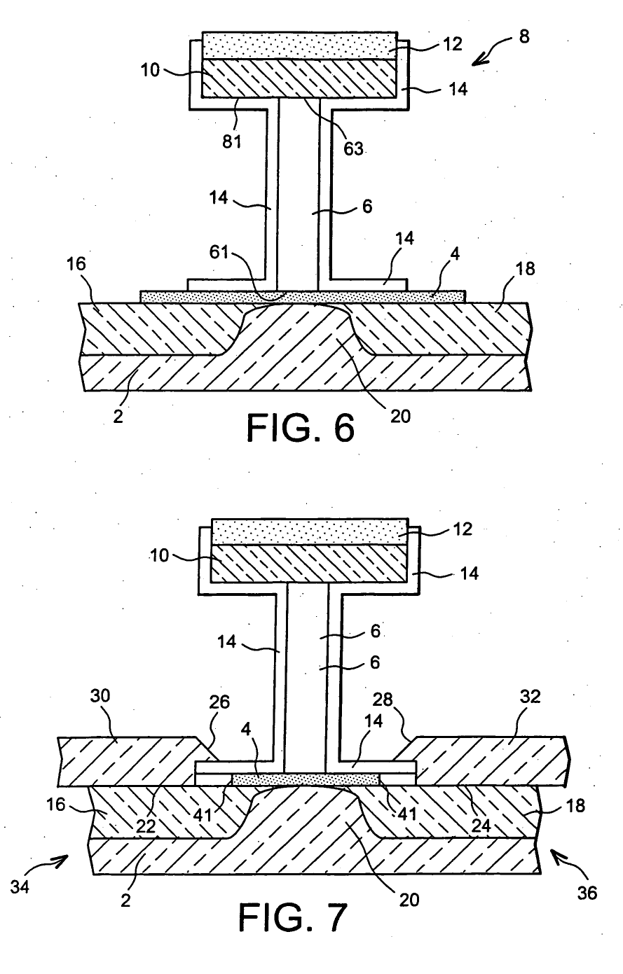

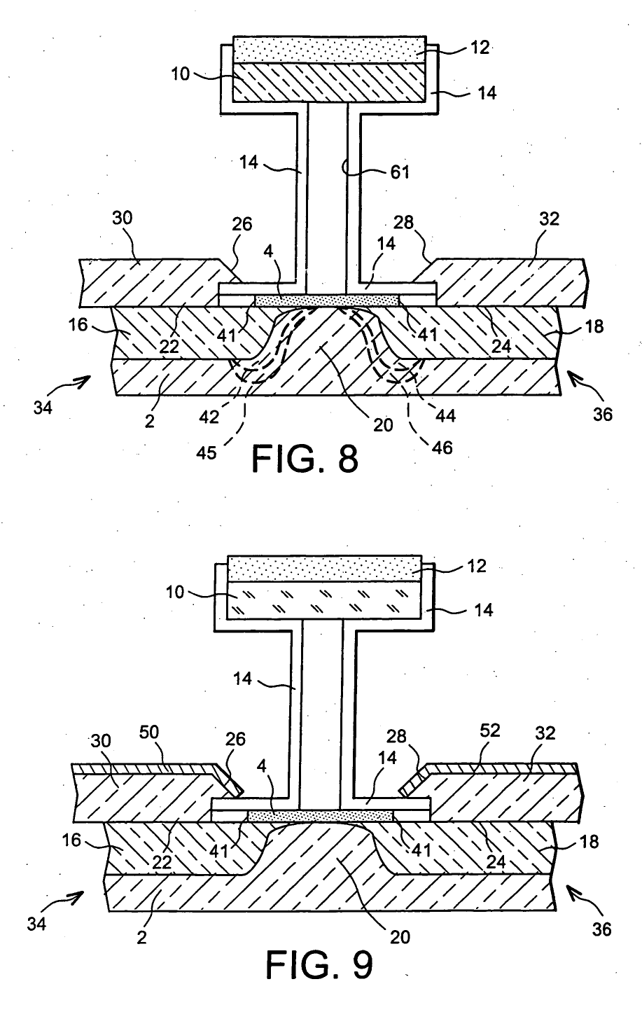

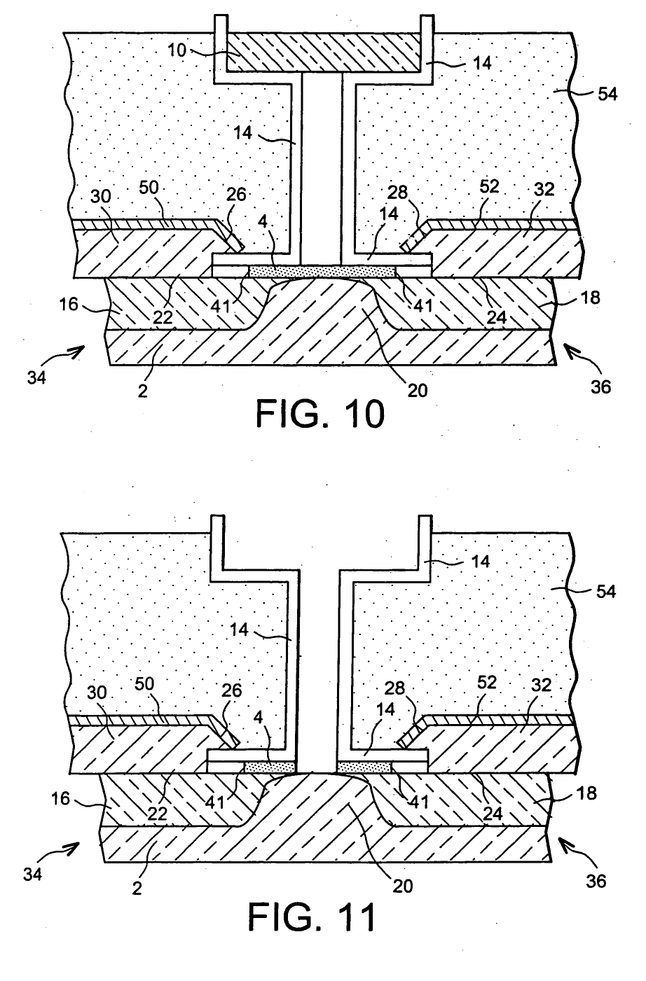

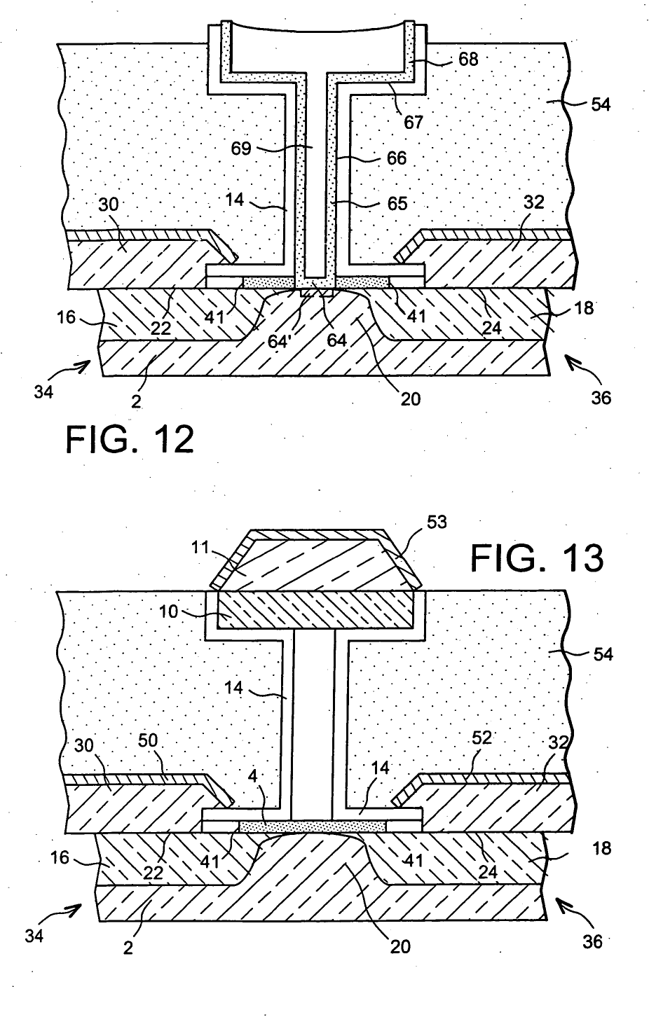

FIGS. 1 to 3 relate to the prior art.

FIGS. 4 to 13 represent transversal cross-section of transistors during manufacture and show the shape that a transistor according to the invention will be called on to become at the end of the method of manufacture.

These figures are more particularly oriented towards the formation of the gate of the transistor since it is said gate that is more specifically concerned by the invention.

In the following description, layers of material are cut or implanted in order to obtain the shapes and the modifications to the properties of the materials of said layer. Whenever there is no confusion possible, the initial layer and what it becomes after treatment have the same reference number.

### DETAILED DESCRIPTION OF SPECIFIC EMBODIMENTS

FIG. 4 represents the shape of a gate formed according to the invention. The method for obtaining said shape will now be described. Said shape is formed on a substrate 2, for example, in p doped silicon. On said substrate is formed a stacking of layers as follows. Firstly, a layer 4 in a high permittivity material, the remainder of said layer will later form a gate or pedestal insulator. Said insulator may be sacrificial or not. It may, for example, be a layer of silica (SiO₂) or a layer of SiOₓN_{y} or hafnium oxide HfO₂, or zirconium oxide ZrO₂ or even aluminium oxide Al₂O₃. Then comes a layer 6 of gate material, sacrificial or not, depending on whether the gate is formed according to a damascene method or not. Said gate material may be, for example, a metal or polycrystalline silicon. Finally, one finds a layer 8 that will be called on to form a hard mask, itself formed of two under layers 10, 12, a first 10 and a second 12. The first under layer 10 may be, for example, an intrinsic poly silicon or a metal or a silicide. The surface under layer 12 may be, for example, a layer of silica. The etching of the hard mask 8 formed by an under layer of intrinsic polycrystalline silicon 10 and an under layer of silica 12 is carried out, to give the shape of the T shaped horizontal bar that will be a part of the shape of the final gate. The vertical bar 6 of the T shaped gate structure is formed by isotropic etching of the layer 6 in metal or in polycrystalline silicon, under the hard mask 8, selectively compared to the gate 4 or pedestal insulator. The role of the layer of silica 12 will subsequently be to avoid the growth of an epitaxial layer and the siliconising of the gate structure. At the end of this first step one obtains the T shape of the future gate. Said shape rests on a pedestal 4, on which rests substantially in its centre the shape of the vertical bar 6 of the T consisting for example of a layer of highly doped (As, boron, phosphorous) polycrystalline silicon or of a layer of Si:Ge:C alloy. The shape of the horizontal bar 8 of the T comes above the vertical bar 6 in the form of the hard mask 8. The vertical bar 6 of the T comprises a lower surface 61 in contact with the insulating layer 4, a lateral surface 62 and an upper surface 63 in contact with the lower under layer 10 of the hard mask 8. The horizontal bar 8 of the T comprises a lower surface 81, a lateral surface 82 and an upper surface 83.

From the state represented in FIG. 4, one arrives at the states represented in FIG. 5 in the following manner.

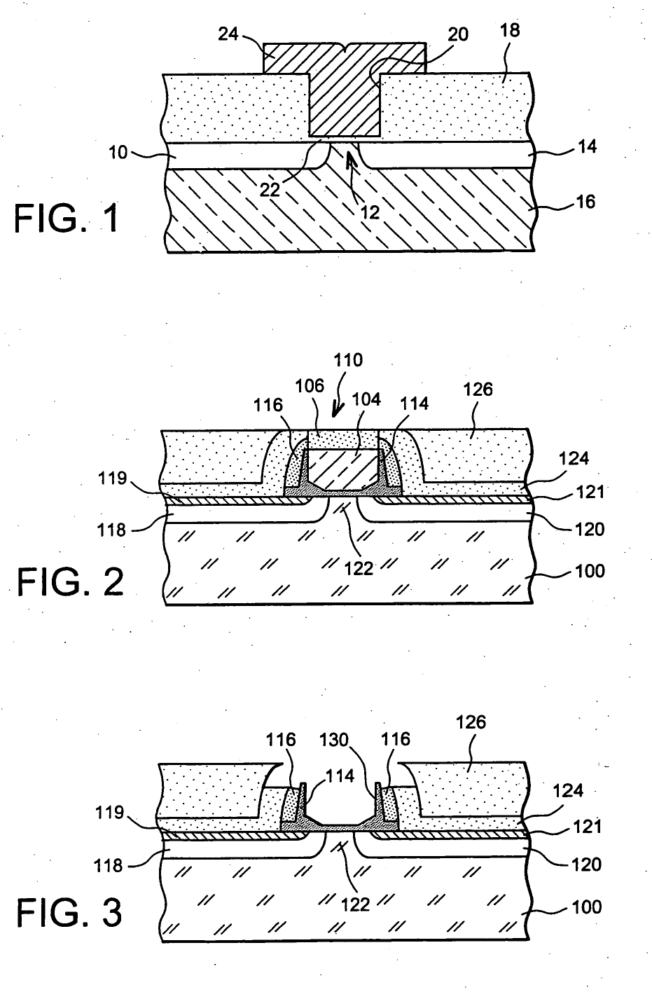

The T shaped structure represented in FIG. 4 is coated with a shaping material 14, the function of which will be to conserve the shape of the T shaped structure up to the end of the manufacturing method. Consequently, it further makes it possible to conserve the size of the patterns. The choice of the shaping material 14 assumes that the different physical and chemical treatments that it will undergo during the manufacturing method will consume it only to a small extent, or even leave it intact. Indeed, the methods for eliminating the hard mask 8, the sacrificial gate formed of the materials contained in the vertical bar 6 and the horizontal bar 8 of the T, the sacrificial oxide 4, and the various cleaning operations preceding the deposition of the definitive gate stacking must leave intact or consume to the least possible extent said shaping material. The shaping material 14 may be deposited by a LPCVD (Low Pressure Chemical Vapour Deposition) technique. Materials such Si₃N₄, HfO₂, ZrO₂ or Al₂O₃ for example are likely to meet the above-mentioned requirements for the shaping material 14. The shaping material 14 represented in FIG. 5 completely coats the T shaped structure represented in FIG. 4, and covers the gate insulating layer 4. One notes in particular that the material 14 completely covers the lateral surface 62 of the vertical bar 6, the lower 81 and upper 83 surfaces of the horizontal bar 8 as well as the lateral surface 82 of said horizontal bar. In the example represented in FIG. 5, the covering of the gate base by the material 14 extends in such a way as to cover a part of zones 16 and 18 which will become, after implantation as explained hereafter, the source and the drain respectively. Obviously, the lower and upper surfaces 61 and 63 of the vertical bar of the T, which are in contact respectively with the oxide of the gate 4 and the lower surface 81 of the T, are not coated. After deposition of the shaping material 14, one forms by masking the complementary n and p zones. According to a first variant, one carries out, in a manner known in itself, the ion implantation of the zones 16 and 18 of the layer 2, which thus become as indicated above the source and the drain. In such a way that the edge of the gate is not masked by the shadow made by the hard mask 8, one will incline the ion implantation beam, as indicated by the arrows in FIG. 5, in such a way that the implanted ions can arrive at the edge of the gate. One thus obtains a gradual source and drain implantation, with a single ion implantation. One thus does away with the necessity of carrying out two successive ion implantations. As described in relation to FIG. 2, one normally carries out in the neighbourhood of the gate a first weak ion implantation, for example, from several 10¹³/cm³ to several 10¹⁴/cm³. A second stronger implantation, for example, from several 10¹⁴ to several 10¹⁵/cm³ is carried out after the application of spacers represented as 116 in FIG. 2. In the embodiment, here described, the hard mask 8 plays among other things the role of spacer. One carries out the rotation of the wafers during the ion implantation in order to conserve the symmetry of the structures.

According to a second variant, the implantation is carried out in a dissymmetric manner as represented in FIG. 5, leading to dissymmetric source and drain zones 16, 18.

Indeed, one exploits a shading effect of the ion implantation due to the hard mask 8 and an inclination of the ion beam such that the dopants do not pass under the gate from a single side, for example the drain side. One then obtains a dissymmetric transistor comprising a zone 19 between the channel zone 20 and the source or the drain, not covered and weakly implanted, represented as dotted lines in FIG. 5 between the channel zone and the drain, may be advantageously exploited for applications other than logic applications. It suffices not to make the substrate rotate during the implantation and to orientate the wafer in such a way that one obtains the dissymmetry, the orientation of the gate structures on the substrate being known by masking.

The interesting applications are

1) High voltage MIS transistors. The avalanche voltage of the drain is increased compared to a transistor implanted in a traditional manner leading to a symmetrical implantation, since the non covering of the gate by the drain adds a series resistance on the drain side to the channel. A part of the applied voltage is transferred to the zone 19 not covered by the gate located between a drain zone 18 not shadowed by the mask 8 and the edge of the gate.

2) Static MIS memories. In this case, one may use the non covered zone 19 a load resistor for flip-flop transistors (See the article “Semiconductor Memories” by D. A. Hodges p. 7, IEEE Press 1972). One may adjust the doping of the substrate on the surface on the drain side in the zone 19 represented with dotted lines, in such a way as to adjust the value of the load resistor on the drain side. Said resistor can quickly reach values of several kohms to several Mohms depending on the doping used. One notes that the adjustment of the series resistance on the drain side is obtained by a 180° orientation of the substrate from the previous implantation, said latter operation favouring the shadowing on the source side.

At the end of this second step, one obtains the shape represented in FIG. 5. Thus, on the substrate 2, has been formed a channel zone 20, corresponding to the non implanted zone of the substrate 2, with on either side implanted source and drain zones 16, 18, respectively as well as the structure in T represented in FIG. 4 coated as indicated above by the shaping material 14. When the implantation is dissymmetric one has in addition a zone 19 weakly implanted compared to the other source and drain zones 16, 18.

From the shapes represented in FIG. 5, one then carries out an anisotropic etching of the shaping material 14. The objective of this etching is to release the source and drain zones 16 and 18 respectively. In FIG. 6, only the shape obtained from a symmetric implantation has been represented.

The shape obtained at the end of this etching is represented in FIG. 6. Compared to the shape represented in FIG. 5, one sees that the upper surface of the shaping material 14, covering the upper surface 83 of the dummy gate and a part of the upper lateral surface 82 of the horizontal bar 8 of the T are no longer covered with the coating material 14. In the same way, the upper part of the gate insulating layer 4 extending on either side of a vertical projection of the horizontal bar 8 of the T of the gate on the plane of the layer 4, is no longer covered with the coating material 14.

From the state represented in FIG. 6, one arrives at the state represented in FIG. 7 in the following manner. One forms the raised source and drain in the following manner. One eliminates the part of the pedestal/gate oxide layer 4 in a selective manner compared to the other materials. One uses for this elimination hydrofluoric acid in the case where the layer 4 is silica SiO₂, otherwise it will be eliminated while dry etching the layer 14. At the end of said elimination there only remains the part of the layer 4 that is located under the horizontal bar of the T. This part of layer 4 is covered with coating material 14. Given the lateral etching of said layer 4, a peripheral zone nevertheless exists, under the coating layer 14 with is etched. This zone has been delimited by lines 41 in FIG. 7. The surfaces cleared by the elimination of a part of the layer 4 and, located immediately above the source and drain 16 and 18 zones, have been marked 22 and 24 respectively. One then forms raised source and drain zones by a selective epitaxy that makes it possible to thicken, from the surfaces 22 and 24, the source and drain 16 and 18 zones respectively. One notes that the growth of the selective epitaxial layer may take place with a faceting at the edge of the pattern. Said faceting has been represented by an inclination 26, 28 of the epitaxial growth layer itself marked 30, 32, said layers 30, 32 being located respectively above the source 16 and drain 18 zones. Given that the exposed part of the hard mask 8 is not made of silicon or any of its alloys, there is no growth of epitaxial layer on the gate structure. At the end of this step, the future transistor has the shape represented in FIG. 7.

Compared to FIG. 6, the source and drain zones have been made bigger by an increased height. A source 34 and a drain 36, are now formed by the part 16 and the epitaxial growth part 30, and by the part 18 and the epitaxial growth part 32 respectively.

In an optional manner, one may, from the state represented in FIG. 5, carry out the etching of the coating layer 14 in order to eliminate the part of said layer beyond a surface located below the horizontal bar of the T. One also eliminates the gate oxide part 4 located under the layer 14 thus reduced. Said etching of the coating 14 also makes disappear the part of the coating 14 located above the upper surface 83 and an upper part of the coating 14 of the lateral surface 82 of the horizontal bar 8 of the T. One then carries out the epitaxial growth of the source and drain 16 and 18 zones from the surfaces 22 and 24 respectively of these zones.

The ion implantation is then carried out after thickening of the source and drain zones in the same manner as that described in relation to FIG. 5. The ion implantation carried out after thickening of the sources and drain 16, 18 makes it possible to reduce the junction depth in the source 16 and drain 18 regions of the buried part in the substrate. In order to make the figure clearer, this reduction in the thickness of the implanted zones 16 and 18 does not appear in FIG. 8, but it should be understood that these zones are less thick in the embodiment described in relation to FIG. 8 than in that described in relation to FIG. 7. Indeed, a part of the doping is retained in the raised epitaxial layer 30, 32. The resistance of the layers of the highly doped source 16 and drain 18 regions remains the same. In this way, the leakage current of the devices thus formed may be reduced. The shape which one ends up with after this implantation, represented in FIG. 8, is the same as that represented in FIG. 7, with the exception of the source and drain zones 16 and 18, the thickness of which is reduced. Also represented in FIG. 8 is a first optional variant where the region of extensions between the channel zone and each of the source 16 and drain 18 regions, has a greater junction depth than the highly doped region. Said regions of greater depth are represented as dotted lines 42 and 44 in FIG. 8. To obtain this result, it suffices to adjust the thickness of the shaping material 14 compared to the thickness of the epitaxial layers 30, 32 of the raised source 16 and drain 18.

According to a second optional variant also represented in FIG. 8, one carries out a second ion implantation, known as pocket implantation. Whereas the ion implantation of regions of greater depth 42 and 44 correspond to the implantation of the source and drain extensions, the second ion implantation is of the same type as the substrate 2, and then of a type opposite to the source and drain implantation. Said implantation takes place in the pockets 45, 46, which are located underneath the zones 42, 44 of the first ion implantation.

The advantage of these embodiments is to make it possible to adjust the series resistance of the source of the transistor under the gate while at the same time limiting the parasite capacity in the raised source and drain contact zones 30 and 32. The pocket implantation 45 and 46 moreover makes it possible to reduce the leakage from the transistors without notably influencing the parasite capacities of the source and the drain 16 and 18, since the thickness of the layer 30 and 32 makes it possible to avoid the penetration of the ions implanted to form the zones 45 and 46 under the zones 16 and 18 respectively.

To carry out the first ion implantation 42 and 44 one uses for example:

As, P, Sb for example if the source and drain are the n type;

B, In, Ga, BF2 for example if the source and drain are the p type;

In order to carry out the pocket implantations 45 and 46 one uses:

B, In, Ga, BF2 for example if the pockets are the p type (n type source and drain);

As, P, Sb for example if the pockets are the n type (p type source and drain).

From the state represented in FIG. 7 or in FIG. 8, the manufacture continues as indicated hereafter.

The manufacturing states represented respectively in FIGS. 9 to 12 correspond to the cases represented in FIG. 7. It should be understood that the continuation of the manufacture from the case represented in FIG. 8 is exactly the same as that which is going to be described now. After the epitaxy in FIG. 7, or the implantation in the case of FIG. 8, one carries out a siliconising of the self aligned source and drain 16, 18. The hard mask is protected superficially by the layer of SiO₂ and laterally by the shape layer 14. At the end of this step, the transistor 1 is in the state represented in FIG. 9. The raised layers 30, 32 are covered respectively by a layer 50, 52 of silicide. In a known manner, said layer of silicide will be used for forming electrical contacts.

From the state represented in FIG. 9, one moves onto the state represented in FIG. 10 in the following manner; one deposits an insulating layer, for example of oxide, 54 said layer covering all of the part represented in FIG. 9 including the T shaped gate. A planarisation of the layer 54 by mechanical-chemical polishing is then carried out. During this operation, one attacks totally the layer 12 of SiO₂ of the hard mask 8 and partially the under layer 10 of intrinsic poly Si or metal or silicide. At the end of this step, one obtains the state represented in FIG. 10. The layer of insulating oxide 54 totally coats the drain and source 34, 36 zones as well as the lateral parts of the vertical bar 6 of the T and comes up to the same level as that which remains of the under layer 10 of intrinsic poly Si. One notes that the lateral parts of the layer 14 that coat the lateral part of the horizontal bar of the T extend above this level.

From the state represented in FIG. 10, one arrives at the state represented in FIG. 11 in the following manner; one eliminates completely the sacrificial gate structure, in other words the layer 10 of intrinsic poly Si forming the horizontal bar of the T as well as the doped intrinsic poly Si or the SiGeC forming the vertical bar of the T. Said elimination is carried out selectively compared to SiO₂ as well as compared to the shaping material 14. At the end of said elimination, one arrives at the state represented in FIG. 11, which differs from the state represented in FIG. 10 by the fact that the internal part of the T has been emptied of its contents, including the base of the T formed by the insulating layer 4.

From the state represented in FIG. 11, in order to terminate the structure, one then carries out the stacking of the definitive gate structure by depositing a gate insulator or by oxidation of the substrate 2.

As represented in FIG. 12, a gate insulating layer 65 totally covers the internal surface of the coating layer 14 as well as the part located immediately above the channel zone 20. The insulating layer 65 thus comprises a part 64 that takes the place of the part of the layer 4 that was found under the surface 63 of the vertical bar of the T. In an optional manner, also represented in FIG. 12, the part 64 of the gate insulating layer 65, may be replaced by a part 64′, represented as broken lines in FIG. 12, obtained by oxidation of the layer 2 at the base of the vertical bar of the T. The gate insulating layer 65 comprises a part 66 covering the internal lateral wall of the layer 14 that formed the vertical bar of the T. It finally comprises parts 67 and 68 that cover respectively the internal surface of the lower part and the lateral part of the horizontal bar of the T. The gate insulating material 65 may be deposited, for example, by an LPCVD type method giving rise to a regular deposition. This deposition is followed by the deposition of a gate material 69 also by LPCVD. A polishing will make it possible to clear the insulated zones not represented and to planarise the gate structure thus formed.

In the embodiment described here, the gate structure has been formed by damascene method.

This structure may also, as represented in FIG. 13, be formed with a material in which the initial gate stacking is not sacrificial. In this case, the gate material and the gate insulator are those that one wishes to end up with. The initial gate material will contribute to the resistance of the gate during the manufacture. While being simpler, this method gives less flexibility with regard to the choice of gate insulating material and of the gate material.

The passage from the state represented for example in FIG. 6, to the state represented in FIG. 13 will now be described briefly while omitting the ion implantation steps and their variants, which are the same as those already described.

After the etching of the coating layer 14 has been carried out, in other words in the state represented in FIG. 6, one carries out the elimination of the layer 12 of the hard mask 8. If said layer 12 is deposited SiO2, one could proceed by diluted HF attack. If the gate insulator 4 is thermal SiO2 it will be eliminated also during this attack but at a rate 3 times lower than the insulator forming the layer 12. An HfO2 type insulator will be attacked with difficulty (or even virtually not attacked) and one eliminates it from the substrate by dry etching while etching the layer 14; idem for ZrO2. On the other hand, Al2O3 will be eliminated at a rate comparable to that of the layer 4 in SiO2. One will observe in this case, a receding of the layer 4 under the layer 14, up to a limit 41, as described in relation to FIG. 7, and a baring of the material 10, which is either polycrystalline Si or metal or silicide. Then, one carries out the self aligned and selective epitaxy on the source and drain 16, 18 regions as well as on the layer 10 forming a layer 11 represented in FIG. 13. The layer 11 replaces on the layer 10, the layer 12 of for example SiO2. One then carries out a self aligned siliconising of zones 50, 52, and 53 above the source and drain sources 30 and 32 and the layer 11 respectively, then a deposition and the planarisation of a deposited oxide 54 in which one may form the contacts on the siliconised zones 50, 52 and 53.

1. Self aligned MIS transistor (1) having a source zone (16,30,34) and a drain zone (18,32,36) on either side of a channel zone (20), as well as a T shaped gate structure comprising a vertical bar (6) located above the channel zone (20), surmounted by a horizontal bar (8) extending on either side of the vertical bar (6), said horizontal bar (8) having a lower part (81), a lateral part (82) and an upper part (83), the gate structure consisting of a stacking of one or several conductive layers (69), a base zone of the gate structure being defined as being around the base of the vertical bar (6) of the T, transistor in which the gate structure is coated with a shaping material (14), said material covering the vertical bar (6) of the T, and the lower (81) and lateral (82) parts of the horizontal bar (8) of the T,
characterised in that said shaping material (14) also covers the base zone of the T shaped structure.

2. Self aligned MIS transistor (1) according to claim 1, characterised in that the base zone covered by the shaping material (14) extends above the source (16,30,34) and drain (18,32,36) zones.

3. Self aligned MIS transistor (1) according to claim 1, characterised in that the first extension zones (42, 44) between the channel (20) and source and drain (16, 18) zones respectively have a doping of the same nature as the source and drain zones (16, 18) but weaker.

4. Self aligned MIS transistor (1) according to claim 1, characterised in that the second extension zones (45, 46) between the channel (20) and source and drain (16, 18) zones respectively have a doping of nature opposite to that of the source and drain zones.

5. Self aligned MIS transistor (1) according to claim 3, characterised in that the second extension zones (45, 46) between the first extension zones (42, 44) and the channel zone (20) have respectively a doping of nature opposite to that of the source and drain zones (16, 18).

6. Self aligned MIS transistor-(I) according to claim 1, characterised in that the shaping material is of silicon nitride (Si₃N₄) or hafnium oxide (HfO₂) or zirconium oxide (ZrO₂) or aluminium oxide (Al₂O₃).

7. Self aligned MIS transistor (1) according to claim 1, characterised in that the stacking of layers constituting the gate structure lodged in the shaping material (14) is intrinsic poly silicon or a metal.

8. Method for manufacturing, on a semiconductor substrate (2), at least one self aligned MIS transistor (1) having a source zone (16,30,34) and a drain zone (18,32,36) on either side of a channel zone (20), as well as a T shaped gate structure of low resistivity comprising a vertical bar (6) located above the channel zone (20), surmounted by a horizontal bar (8) extending on either side of the vertical bar (6), said horizontal bar (8) having a lower part (81), a lateral part (82) and an upper part (83), the gate structure consisting of a stacking of one or several conductive layers (69), a base zone of the gate structure being defined as being around the base of the vertical bar (6) of the T, the method comprising a step of forming a solid shape having the T shape of the grid that one wishes to form, and the coating of said shape in a shaping material (14), said shaping material (14) coating the lateral surface (62) of the vertical bar (6) of the T, the lower (81) and lateral (82) surfaces of the horizontal bar of the T,
characterised in that said shaping material (14) also covers the base zone of the definitive gate structure.

9. Method according to claim 8 characterised in that the shaping material covers a part at least of the source and drain zones (16, 18).

10. Method according to claim 8 characterised in that the shaping material is silicon nitride (Si₃N₄) or hafnium oxide (HfO₂) or zirconium oxide (ZrO₂) or aluminium oxide (Al₂O₃).
